(19) United States
(12) Patent Application Publication
(10) Pub. No.: US 2011/0104903 A1
(43) Pub. Date: May 5, 2011

(54) MANUFACTURING APPARATUS AND METHOD FOR SEMICONDUCTOR DEVICE

(75) Inventor: Akihiro Takase, Oita-ken (JP)

(73) Assignee: KABUSHIKI KAISHA TOSHIBA, Tokyo (JP)

(21) Appl. No.: 12/796,196

(22) Filed: Jun. 8, 2010

(30) Foreign Application Priority Data
Oct. 30, 2009 (JP) 2009-250383

(51) Int. Cl. H01L 21/3065; H01L 21/31; B05C 11/00; B05C 21/00

(52) U.S. Cl. 438/716; 438/758; 156/345.26; 118/668; 257/E21.218; 257/E21.24

(57) ABSTRACT

A manufacturing apparatus for a semiconductor device, comprising: a chamber configured to process a wafer; a wafer stage installed in the chamber and formed with a plurality of holes for supplying gas to a rear surface of the wafer; a gas detection mechanism configured to detect an amount of gas leak from each of the plurality of holes, independently; a wafer position detection mechanism configured to determine a direction and an amount of a deviation of the wafer from a predetermined position on the wafer stage based on the detected amounts of gas leak of a hole and positions of the hole; and a wafer position adjustment mechanism configured to adjust a position of the wafer based on the direction and the amount of the deviation of the wafer from the predetermined position on the wafer stage.

### CROSS-REFERENCE TO RELATED APPLICATION

This application is based upon and claims the benefit of priority from the prior Japanese Patent Application No. 2009-250383 filed on Oct. 30, 2009, the entire contents of which are incorporated herein by reference.

### BACKGROUND OF THE INVENTION

The present invention relates to a manufacturing apparatus and method for a semiconductor device using plasma processing technology, for example.

Generally, plasma processing is used to perform etching and film formation in a process of manufacturing semiconductor devices. Usually, in using the plasma processing, a semiconductor substrate, hereinafter referred to as a wafer, is loaded into a plasma processing apparatus and placed on a wafer stage using a transfer arm or the like.

At this time, a positional deviation may occur between the wafer and the wafer stage due to a warp in the wafer resulting from a temperature distribution or a film structure on a rear surface or from variations in controlling the transfer arm, or for some other reason. Then, there is posed a problem that an edge of the wafer placed on a member such as a focus ring usually provided on an outer circumference of the wafer stage, so that a self bias lowers to such a level that it becomes difficult to obtain desired plasma characteristics.

In recent years, with growing requirement for improvement in film quality to be adaptable to miniaturization and high-speed manufacture of a semiconductor device, progress is being made toward plasma processing using higher frequency, and further improvement of precision in placing a wafer has been required. Accordingly, Japanese Patent Application Laid-Open No. 10-125769 (paragraph [0022], etc.) discloses a technique of detecting a gas leak from a gas introduction hole for temperature control formed in an electrostatic chuck electrode on which a wafer is placed to detect a holding state of the wafer. However, disadvantageously, the quantity and direction of a deviation of a wafer cannot be detected according to the technique. Besides, since deviation cannot be adjusted even though the presence and absence of the deviation is detected, it is difficult to improve the precision in placing a wafer.

### SUMMARY

According to an aspect of the present invention, there is provided a manufacturing apparatus for a semiconductor device, including: a chamber configured to process a wafer; a wafer stage installed in the chamber and formed with a plurality of holes for supplying gas to a rear surface of the wafer; a gas detection mechanism configured to detect an amount of gas leak from each of the plurality of holes, independently; a wafer position detection mechanism configured to determine a direction and an amount of a deviation of the wafer from a predetermined position on the wafer stage based on the detected amounts of gas leak of a hole and positions of the hole; and a wafer position adjustment mechanism configured to adjust a position of the wafer based on the direction and the amount of the deviation of the wafer from the predetermined position on the wafer stage.

According to an aspect of the present invention, there is provided a manufacturing method for a semiconductor device, including: loading a wafer into a chamber and placing the wafer on a wafer stage having a plurality of holes for supplying gas to a rear surface of the wafer, each of the holes being arranged in a predetermined position of the wafer stage; supplying the gas to the plurality of holes to detect a leak of the supplied gas from the holes; and determining a direction and an amount of a deviation of the wafer based on the detected leak of the gas.

### BRIEF DESCRIPTION OF THE DRAWINGS

FIG. 1 illustrates a configuration of a plasma processing apparatus according to an aspect of the present invention;

FIG. 2 illustrates a more detailed structure of a wafer stage according to an aspect of the present invention;

FIG. 3 illustrates arrangement of cooling gas holes according to an aspect of the present invention;

FIG. 4 is a flowchart of a semiconductor manufacturing process according to an aspect of the present invention;

FIG. 5 is a cross-sectional view of a wafer w in a diametrical direction when the wafer w is placed in proper position, according to an aspect of the present invention;

FIG. 6 is a cross-sectional view of a wafer w in a diametrical direction when a deviation of the wafer w is large, according to an aspect of the present invention;

FIG. 7 is a cross-sectional view of a wafer w in a diametrical direction when a deviation of the wafer w is small, according to an aspect of the present invention;

FIG. 8 illustrates an arrangement of cooling gas holes and a position of a wafer w according to an aspect of the present invention; and

FIGS. 9A to 9C and 10A to 10C illustrate a wafer movement method according to an aspect of the present invention.

### DETAILED DESCRIPTION

Reference will now be made in detail to the present embodiment of the invention, an example of which is illustrated in the accompanying drawings. Wherever possible, the same reference numbers will be used throughout the drawing to refer to the same or like parts.

Embodiments according to the present invention will be described with reference to the accompanying drawings.

### First Embodiment

FIG. 1 illustrates a configuration of a plasma processing apparatus that is a manufacturing apparatus for a semiconductor device according to the present embodiment. As illustrated in FIG. 1, for example, in a chamber 10 for plasma processing of a wafer w, an upper electrode 12 and a wafer stage 14 are provided. The wafer stage 14 is disposed to face the upper electrode 12 and serves as a lower electrode.

The chamber 10 is provided with gas introduction ports 16 and exhaust ports 18. The gas introduction ports 16 are connected with a process gas supply mechanism (not illustrated) including a mass flow controller for introducing process gas of a predetermined gas type and flow rate from the above. The exhaust ports 18 are provided for exhausting surplus process gas, reaction by-product and the like. The exhaust ports 18 are connected with an exhaust mechanism (not illustrated) including a vacuum pump, an exhaust regulating valve, thereby to control a pressure in the chamber 10 to a predetermined pressure.

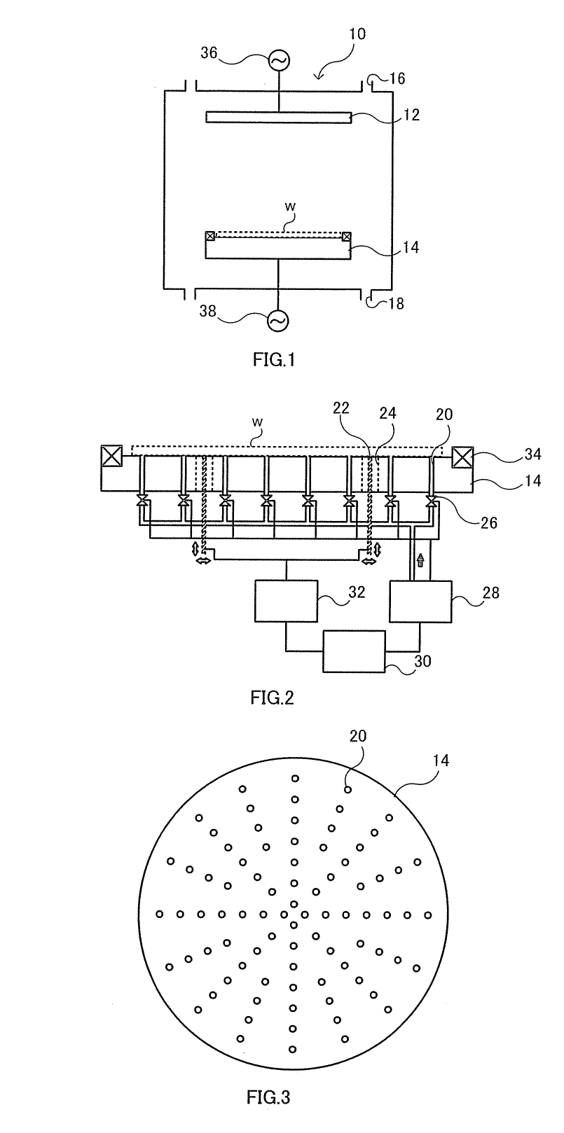

FIG. 2 illustrates a more detailed structure of the wafer stage 14 that serves as a lower electrode. The wafer stage 14 is provided with a plurality of cooling gas holes 20 for supplying cooling gas to a rear surface of a wafer to keep a wafer temperature constant, and pin holes 24 for supporting the wafer w at a tip thereof to move the wafer w. Each of the pin holes 24 is a hole of φ7 to 8 mm, for example, through which a pin 22 passes. The pin 22 has a diameter of φ1 to 2 mm, for example. The pin 22 is positioned in the center of the pin hole 24, in which a gap (play) of 3 mm, for example, is formed between the pin hole 24 and the pin 22.

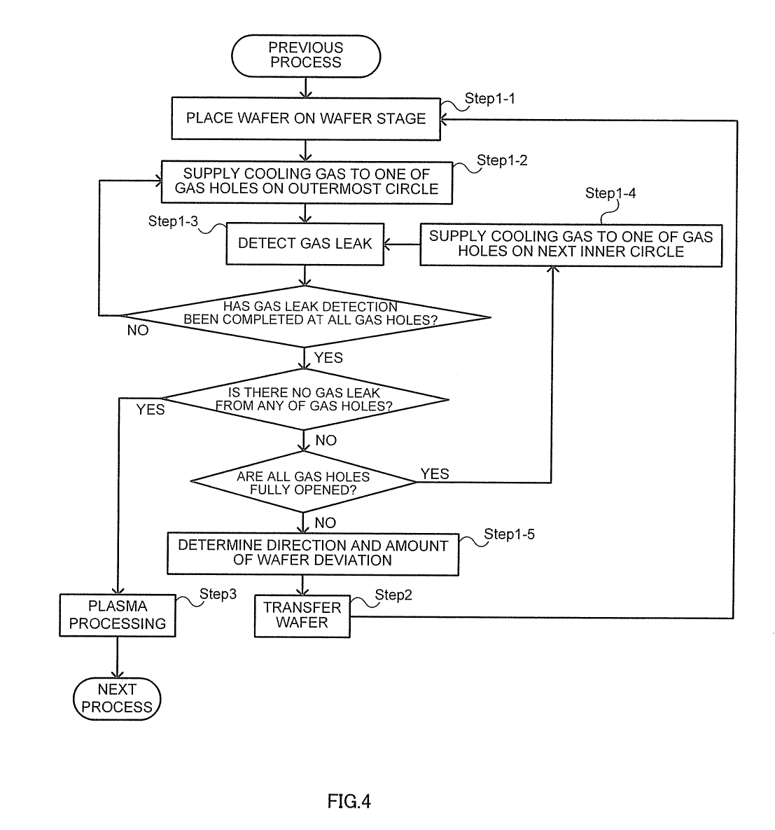

The cooling gas holes 20, as FIG. 3 illustrates an arrangement thereof, for example, are formed at predetermined intervals in a circumferential direction of the wafer stage 14 and concentrically at predetermined pitches (e.g., at intervals of 5 mm) in a diametrical direction of the wafer stage 14 as well. Besides, each of the cooling gas holes 20 is connected with each of valves 26 and a cooling gas supply mechanism 28. Each of the valves 26 independently supplies cooling gas to each of the cooling gas holes 20. The cooling gas supply mechanism 28 includes a leak detection mechanism that controls the valves 26 and detects a leak of the cooling gas from each of the cooling gas holes 20 by using a pressure gauge or the like.

The cooling gas supply mechanism 28 is connected with a wafer position detection mechanism 30 and a wafer position adjustment mechanism 32. The wafer position detection mechanism 30 is provided with a calculation unit for determining a deviation of a wafer w from a proper placement position based on the detected cooling gas leak from each of the cooling gas holes 20. The wafer position adjustment mechanism 32 is configured to control the pin 22 so that the pin 22 moves vertically and in a predetermined direct ion within a wafer w plane based on the determined deviation state.

Further, on the wafer stage 14, an insulating focus ring 34 is attached. The focus ring 34 allows reactive ions produced by plasma to effectively react with a wafer w placed on the inside thereof.

The upper electrode 12 and the wafer stage 14 serving as a lower electrode are respectively connected with high-frequency power sources 36, 38 for applying a high-frequency voltage. In a process where no bias is applied, the wafer stage 14 is grounded.

Using such a plasma processing apparatus, the wafer w is subjected to plasma processing as illustrated in FIG. 4.

The wafer w is loaded into the chamber 10 by a transfer arm (not illustrated). The loaded wafer w is supported on a tip of the pins 22 that are moved up, and the pins 22 are then moved down to place the wafer w on the wafer stage 14 (Step 1-1).

The valves 26 are controlled by the cooling gas supply mechanism 28 and cooling gas consisting of He gas is supplied at 20 sccm, for example, into one of the cooling gas holes 20 on an outermost circle so that a pressure within the system reaches a predetermined pressure (Step 1-2).

The cooling gas is sequentially supplied into the respective cooling gas holes 20 on the outermost circle in this way and pressure changes in the cooling gas within all the cooling gas holes 20 are detected. The cooling gas supply mechanism 28 monitors a pressure drop within the system, for example, thereby to detect a cooling gas leak from each of the cooling gas holes 20 (Step 1-3).

For example, in a case where the wafer w is placed in a proper position as illustrated in FIG. 5 that is a cross-sectional view of the wafer w in a diametrical direction, no cooling gas leak occurs from cool ing gas holes 20a, 20b on the outermost circle so that no pressure drop occurs within the system.

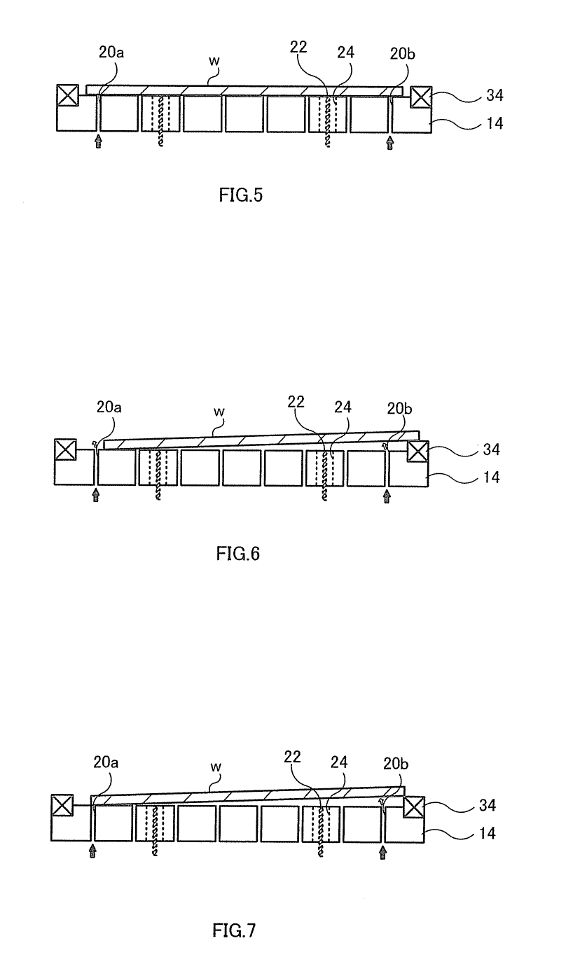

FIG. 6 illustrates a cross-sectional view of the wafer w in a diametrical direction in a case where the position of the wafer w is largely deviated from the proper position thereof as a result of an end portion of the wafer w being on the focus ring 34. Since cooling gas flows out of the cooling gas hole 20a not covered with the wafer w and the cooling gas hole 20b spaced from the wafer stage 14 by a length substantially equal to the height (700 μm, for example) of the focus ring 34, a pressure within the system obviously drops, thereby the presence of leakage is detected.

FIG. 7 is a cross-sectional view of the wafer w in a diametrical direction in a case where the position of the wafer w is slightly deviated from the proper position thereof although the end portion of the wafer w is on the focus ring 34. While the cooling gas hole 20b is open as in the case of FIG. 6, a gap between the wafer w and the wafer stage 14 above the cooling gas hole 20a is very small, that is, on the order of several μm or less. Accordingly, it is detected that the leakage is less than in the case where the cooling gas hole is fully open (or that a pressure drop within the system due to flowing-out of cooling gas is suppressed).

Thus, a leak of cooling gas from all the cooling gas holes 20 on the outermost circle is detected. Based on the detection result, the presence/absence and direction of a deviation of the wafer w are obtained.

In the case where the end portion of the wafer w is on the focus ring 34, a self bias lowers more than in the case where the end portion of the wafer w is not on the focus ring 34; therefore, there is a problem that it is difficult to attain desired plasma characteristics. This is considered to be caused by an increase in an area to be processed and/or generation of space potential loss. Besides, it is considered that it is more difficult that a high-frequency voltage producing plasma jumps across the space as the frequency is higher; therefore, such a problem becomes more significant as the frequency is higher. Accordingly, when a leak of cooling gas from the cooling gas hole 20 is detected, a placement position of the wafer w needs to be corrected.

When no cooling gas leak is found from any of the cooling gas holes 20 on the outermost circle, which indicates that no deviation occurs in the wafer w, the wafer w is subjected to plasma processing in this state, as will be described later (Step 3).

When cooling gas leak occurs from all the cooling gas holes 20 on the outermost circle, a leak of cooling gas from the cooling gas holes 20 positioned on the next inner circle is detected as in the case of the cooling gas holes 20 on the outermost circle by monitoring a pressure drop within the system for each of the cooling gas holes 20 positioned on the next inner circle (Step 1-4). When cooling gas leak occurs from all the cooling gas holes 20 on the next inner circle, the process proceeds to detection of a gas leak from the cooling gas holes 20 on the next next inner circle.

Subsequently, a method for determining a deviation direction of the wafer w based on a state of a cooling gas leak from the cooling gas holes 20 will be described. FIG. 8 illustrates an example of a positional relationship between an arrangement of cooling gas holes and a position of the wafer w (broken line). FIG. 8 illustrates a state of a pressure drop in the cooling gas holes 20 shown by black circles. A deviation direction of the wafer can be determined from positions of the cooling gas holes 20 having internal pressure drops.

Specifically, since the wafer w has a circular shape, when positions of all the cooling gas holes 20 having pressure drops are known, it can be said that the wafer w deviates in a central direction of the wafer stage 14 having a symmetric axis with respect to which the most positions of all of the cooling gas holes 20 are symmetric.

A deviation amount Δd can be determined from a position and a pressure drop amount of the cooling gas hole 20 having a pressure drop. The deviation amount of the wafer w corresponding to the positions of the cooling gas holes 20 having a pressure drop and the pressure drop amount thereof may be obtained in advance. The deviation direction and amount of the wafer w are thus determined from a leak state (leak amount and distribution thereof) of cooling gas (Step 1-5).

The wafer position adjustment mechanism 32 drivingly controls the wafer w having the determined deviation amount so that the wafer w is moved by the amount corresponding to the deviation in a reverse direction to a direction of the detected deviation (Step 2).

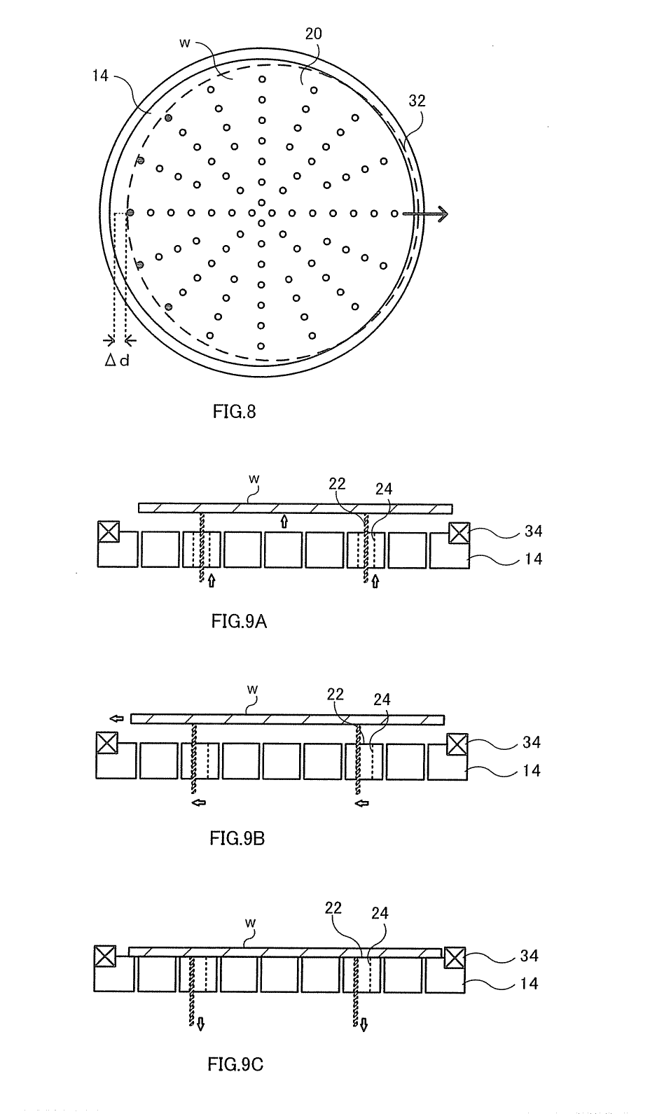

For example, as illustrated in FIG. 9A, the pins 22 are moved up to support the wafer w on the pins 22. As illustrated in FIG. 9B, the pins 22 are moved in a reverse direction to the deviation direction of the wafer w. At this time, the wafer w can be moved by 3 mm at a maximum as the pin hole 24 through which the pin 22 passes has a play of 3 mm, for example.

After the wafer w is moved, the pins 22 are moved down and the wafer w is placed on the wafer stage 14 and the process returns to Step 1-1. After the wafer w is placed on the wafer stage 14, the pins 22 may be moved in a predetermined position, for example, in the center of the pin holes 24.

To check for presence of a deviation after the wafer w is moved in this way, a state of cooling gas leak from the cooling gas holes 20 at each phase on the outermost circle may be detected by supplying cooling gas to the cooling gas holes 20 again. To perform second detection for gas leak, Steps 1-1 to 1-5 and Step 2 are repeated until no cooling gas leak is found from any of the cooling gas holes 20 on the outermost circle.

When no cooling gas leak is found from any of the cooling gas holes 20 on the outermost circle, that is, when it is confirmed that the position of the wafer w is corrected to the proper position, process gas is introduced into the chamber 10, a high-frequency voltage is applied to the upper electrode 12 and the wafer stage 14, so that the wafer w is subjected to plasma processing (Step 3).

By adjusting the deviation of the wafer w in this way, the accuracy of placing the wafer w can be improved and desired plasma characteristics can be attained in the plasma processing.

### Second Embodiment

In the first embodiment described above, a deviation of a wafer w is adjusted by moving the position of the wafer w using the pins 22; however, means subjected to driving control by the position adjustment mechanism 32 is not limited to the pins 22. In the present embodiment, an example of adjusting a deviation of a wafer w by controlling a working distance and a working direction of a transfer arm for transferring the wafer w will be described below. A process of determining the direction and amount of a deviation is substantially the same as in the first embodiment; therefore, the overlapping description will not be repeated.

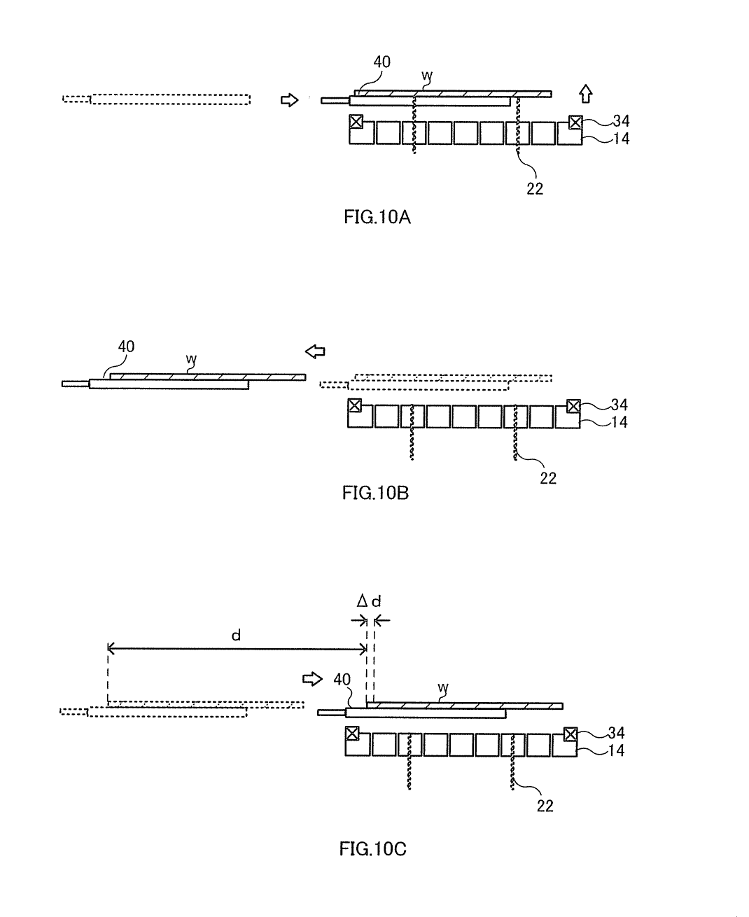

As illustrated in FIG. 10A, the wafer w is moved up by the pins 22 and a transfer arm 40 is inserted into the chamber to place the wafer w on the transfer arm 40.

As illustrated in FIG. 10B, the wafer w is unloaded to the outside of the chamber, into a transfer chamber, for example, by the transfer arm 40. As illustrated in FIG. 10C, a working distance of the transfer arm 40 is controlled so that the wafer w is moved by the amount corresponding to a detected deviation in a reverse direction to the deviation direction prior to second loading of the wafer w. In other words, the working distance is controlled so that the working distance upon the second loading is d+Δd, where d is the first working distance and Δd is the deviation amount. After the pins 22 are moved up to support the wafer w, the pins 22 are moved down to place the wafer w on the wafer stage 14 again.

The present embodiment illustrates a case where a deviation is caused by a working distance of the transfer arm; however, adjustment can similarly be made as in the case of a deviation occurring in the working direction of the transfer arm.

By adjusting the deviation of the wafer w in this way, the accuracy of placing the wafer w can be improved and desired plasma characteristics can be attained in the plasma processing.

The present embodiment describes an application to plasma processing; however, the present embodiment is applicable to a process where plasma is not used when a wafer is attracted onto the stage in the process. For example, such process includes a process of repairing damage of an insulation film (low-k film) having a low dielectric constant used as an interlayer insulation film or the like. Process gas used in plasma processing is not particularly limited and may include process gas containing film-forming gas such as SiH₄ or etching gas such as CF₄, depending upon the purpose thereof.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A manufacturing apparatus for a semiconductor device, comprising:
a chamber configured to process a wafer;
a wafer stage installed in the chamber and formed with a plurality of holes for supplying gas to a rear surface of the wafer;
a gas detection mechanism configured to detect an amount of gas leak from each of the plurality of holes, independently;
a wafer position detection mechanism configured to determine a direction and an amount of a deviation of the wafer from a predetermined position on the wafer stage based on the detected amounts of gas leak of a hole and positions of the hole; and
a wafer position adjustment mechanism configured to adjust a position of the wafer based on the direction and the amount of the deviation of the wafer from the predetermined position on the wafer stage.

2. The manufacturing apparatus for a semiconductor device according to claim 1, wherein the wafer stage includes pinholes, each of the pin holes has a predetermined gap between the pin hole and a pin, and the pin is configured to support the wafer loaded in the chamber and to move down to place the wafer on the wafer stage.

3. The manufacturing apparatus for a semiconductor device according to claim 2, wherein the wafer position adjustment mechanism moves the pin based on the direction and the amount of the deviation to move the wafer.

4. The manufacturing apparatus for a semiconductor device according to claim 1, wherein the wafer position adjustment mechanism includes a transfer arm configured to transfer the wafer to the chamber and that adjusts a working distance and a working direction thereof based on the direction and the amount of the deviation.

5. The manufacturing apparatus for a semiconductor device according to claim 1, wherein the plurality of holes are formed in a circumferential direct ion of the wafer stage at predetermined pitches.

6. The manufacturing apparatus for a semiconductor device according to claim 5, wherein the plurality of holes are arranged in a plurality of concentric circles with different radii.

7. The manufacturing apparatus for a semiconductor device according to claim 1, wherein the gas detection mechanism detects a pressure drop of the gas in the plurality of holes for supplying the gas.

8. The manufacturing apparatus for a semiconductor device according to claim 1, wherein the gas is gas for cooling a wafer.

9. The manufacturing apparatus for a semiconductor device according to claim 1, further comprising a plasma electrode and a supply mechanism of process gas.

10. The manufacturing apparatus for a semiconductor device according to claim 9, wherein the process gas is etching gas.

11. The manufacturing apparatus for a semiconductor device according to claim 9, wherein the process gas is film-forming gas.

12. A manufacturing method for a semiconductor device, comprising:
loading a wafer into a chamber and placing the wafer on a wafer stage having a plurality of holes for supplying gas to a rear surface of the wafer, each of the holes being arranged in a predetermined position of the wafer stage;
supplying the gas to the plurality of holes to detect a leak of the supplied gas from the holes; and
determining a direction and an amount of a deviation of the wafer based on the detected leak of the gas.

13. The manufacturing method for a semiconductor device according to claim 12, wherein the plurality of holes are formed in a circumferential direction of the wafer stage at predetermined pitches; and
the detecting of a leak of the gas from the holes includes sequentially supplying the gas into each of the plurality of holes to detect a leak of the supplied gas from the holes.

14. The manufacturing method for a semiconductor device according to claim 13, wherein the plurality of holes are arranged in a plurality of concentric circles with different radii and, when a gas leak occurs from all holes positioned on an outer circle is detected, a leak of the gas is further detected from holes positioned on an inner circle.

15. The manufacturing method for a semiconductor device according to claim 12, wherein a position of the wafer is adjusted based on the determined direction and amount of the deviation.

16. The manufacturing method for a semiconductor device according to claim 15, wherein the position of the wafer is adjusted by moving up a pin disposed below the wafer to support the wafer on the pin and moving the pin.

17. The manufacturing method for a semiconductor device according to claim 15, wherein the position of the wafer is adjusted by unloading the wafer from the chamber and loading the wafer again.

18. The manufacturing method for a semiconductor device according to claim 15, wherein after the position of the wafer is adjusted, a leak of the gas is detected again.

19. The manufacturing method for a semiconductor device according to claim 15, wherein after the position of the wafer is adjusted, the wafer is subjected to plasma processing.

20. The manufacturing method for a semiconductor device according to claim 19, wherein the plasma processing is etching processing or film formation processing.
